(19) United States
(12) Patent Application Publication
(10) Pub. No.: US 2011/0007453 A1
(43) Pub. Date: Jan. 13, 2011

(54) METHOD FOR FORMING A CONCAVO-CONVEX TEXTURED STRUCTURE ON A HOUSING OF AN ELECTRONIC DEVICE AND RELATED STRUCTURE

(76) Inventors: Chen-Feng Hsieh, Taipei Hsien (TW); Ya-Chi Hsiao, Taipei Hsien (TW)

Correspondence Address: NORTH AMERICA INTELLECTUAL PROPERTY CORPORATION, P.O. BOX 506, MERRIFIELD, VA, 22116, US

(21) Appl. No.: 12/499,094

(22) Filed: Jul. 8, 2009

(51) Int. Cl. G05B 19/4097; G05B 19/19; C23F 1/00; B24C 1/00; H05K 5/00

(52) U.S. Cl. 361/679.01; 700/160; 700/118; 216/37; 451/28; 264/299; 700/187

(57) ABSTRACT

A method is used for forming a concavo-convex textured structure on a housing of an electronic device. The method includes providing a CAM (Computer-Aided Manufacturing) drawing corresponding to the concavo-convex textured structure, inputting the CAM drawing into a CNC (Computer Numerical Control) milling machine, disposing a workpiece on the CNC milling machine, and utilizing the CNC milling machine to mill the concavo-convex textured structure on the workpiece according to the CAM drawing, and utilizing the workpiece to manufacture the housing of the electronic device.

### BACKGROUND OF THE INVENTION

1. Field of the Invention

The present invention relates to a method for forming a concavo-convex textured structure on a housing of an electronic device and related structures, and more specifically, to a method for forming a concavo-convex textured structure on a housing of an electronic device and related structures by a CNC milling process.

2. Description of the Prior Art

In recent years, a common method for forming a concavo-convex textured structure on a housing of an electronic device, such as a covering of a notebook computer, involves performing a chemical etching process on a surface of the housing. The said chemical etching process can be divided into two types: a direct etching method and an indirect etching method. The direct etching method involves coating an etching resist layer on a workpiece, utilizing a UV exposure process to form an etching mask on the workpiece, and performing a chemical etching process on the workpiece. The indirect etching method involves printing an etching resist layer on a transfer paper, pasting the transfer paper on the workpiece for transferring the etching resist layer to the workpiece, and performing a chemical etching process on the workpiece.

However, the said methods may only be capable of forming a simple textured structure on the workpiece since the chemical solution used in the chemical etching process can just etch the surface of the workpiece vertically and shallowly. If a complicated textured structure is desired to form on the surface of the workpiece, the said etching process needs to be performed on the surface of the workpiece repeatedly. Thus, related manufacturing processes are strenuous and time-consuming.

Furthermore, because the chemical solution used in the chemical etching process can just etch the surface of the workpiece vertically, a concavo-convex textured structure on a workpiece formed by the chemical etching process cannot have a smooth outline. Thus, if the workpiece is utilized as a mold for molding an ink layer of a film in an IMR (In Mold Roller) process, the film may be incapable of attaching to the workpiece closely and completely due to the unsmooth structure on the workpiece. In such a manner, the film may be broken during the IMR process.

In summary, how to manufacture a complicated and smooth textured structure on a housing of an electronic device quickly should be a concern in surface machining.

### SUMMARY OF THE INVENTION

The present invention provides a method for forming a concavo-convex textured structure on a housing of an electronic device, the method comprising providing a CAM (Computer-Aided Manufacturing) drawing corresponding to the concavo-convex textured structure; inputting the CAM drawing into a CNC (Computer Numerical Control) milling machine, disposing a workpiece on the CNC milling machine; utilizing the CNC milling machine to mill the concavo-convex textured structure on the workpiece according to the CAM drawing; and utilizing the milled workpiece to manufacture the housing of the electronic device.

The present invention further provides a housing for an electronic device, the housing comprising a main body; and a concavo-convex textured structure formed on the main body by utilizing a CNC milling machine according to a CAM drawing.

The present invention further provides an electronic device comprising a device body; and a housing disposed on the device body, the housing comprising a main body; and a concavo-convex textured structure formed on the main body by utilizing a CNC milling machine according to a CAM drawing.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram of an electronic device according to a first preferred embodiment of the present invention.

FIG. 2 is a flowchart of a method for forming a concavo-convex textured structure on a main body of the housing in FIG. 1 according to the first preferred embodiment of the present invention.

FIG. 3 is a partial cross-sectional diagram of an unmilled workpiece with an etching-resist glue layer.

FIG. 4 is a partial cross-sectional diagram of the workpiece in FIG. 3 having a concavo-convex textured structure thereon according to the first preferred embodiment of the present invention.

FIG. 5 is a diagram of an electronic device according to a second preferred embodiment of the present invention.

FIG. 6 is a flowchart of a method for forming the housing in FIG. 5 according to the second preferred embodiment of the present invention.

FIG. 7 is a partial cross-sectional diagram of an unmilled workpiece according to the second preferred embodiment of the present invention.

FIG. 8 is a partial cross-sectional diagram of the milled workpiece having a concavo-convex textured structure thereon according to the second preferred embodiment of the present invention.

FIG. 9 is a partial cross-sectional diagram of the milled workpiece in FIG. 8 being utilized as a female mold according to the second preferred embodiment of the present invention.

FIG. 10 is a partial cross-sectional diagram of a film with an ink layer being attached to the milled workpiece in FIG. 8 according to the second preferred embodiment of the present invention.

FIG. 11 is a partial cross-sectional diagram of a concavo-convex textured structure and a main body of the housing being formed between the milled workpiece and a male mold in FIG. 10 according to the second preferred embodiment of the present invention.

### DETAILED DESCRIPTION

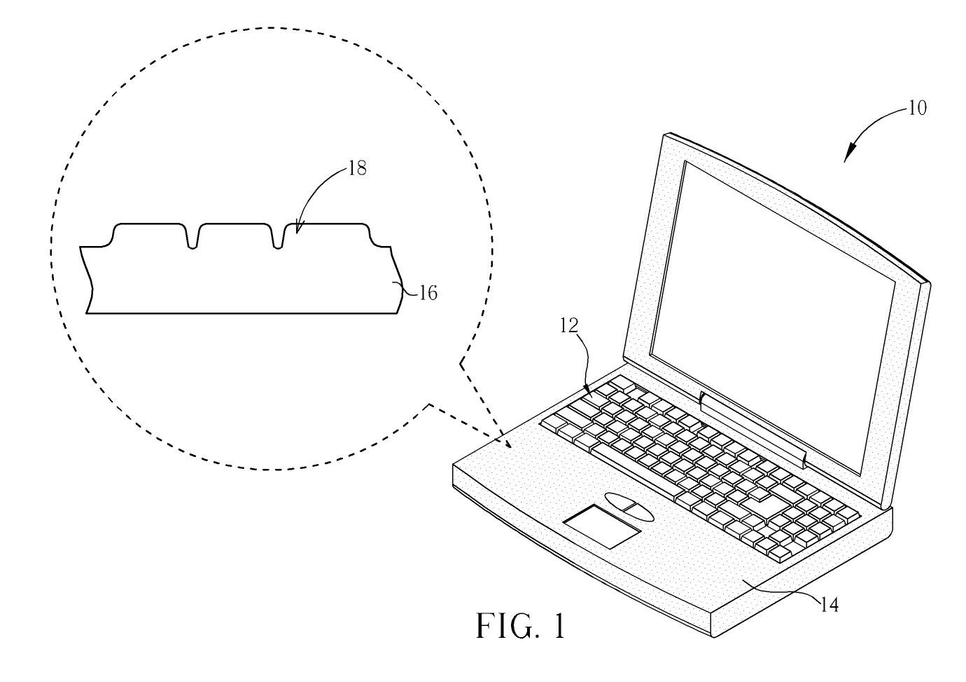

Please refer to FIG. 1, which is a diagram of an electronic device 10 according to a first preferred embodiment of the present invention. As shown in FIG. 1, the electronic device 10 is a notebook, but the present invention is not limited thereto, meaning that the present invention may also be applied for other electronic device, such as a mobile phone, a PDA (Personal Digital Assistant), etc. The electronic device 10 includes a device body 12 and a housing 14. In the present invention, the device body 12 is regarded as the combination of other components (e.g. a keyboard, an LCD monitor, a motherboard, etc.) besides the housing 14 in the electronic device 10. The housing 14 is disposed on the device body 12 for protection of the device body 12. The housing 14 includes a main body 16 and a concavo-convex textured structure 18. As shown in FIG. 1, the concavo-convex textured structure 18 is formed on the main body 16. In the present invention, a CNC milling process is utilized to form the concavo-convex textured structure 18. More detailed description for forming the concavo-convex textured structure 18 on the main body 16 is provided as follows.

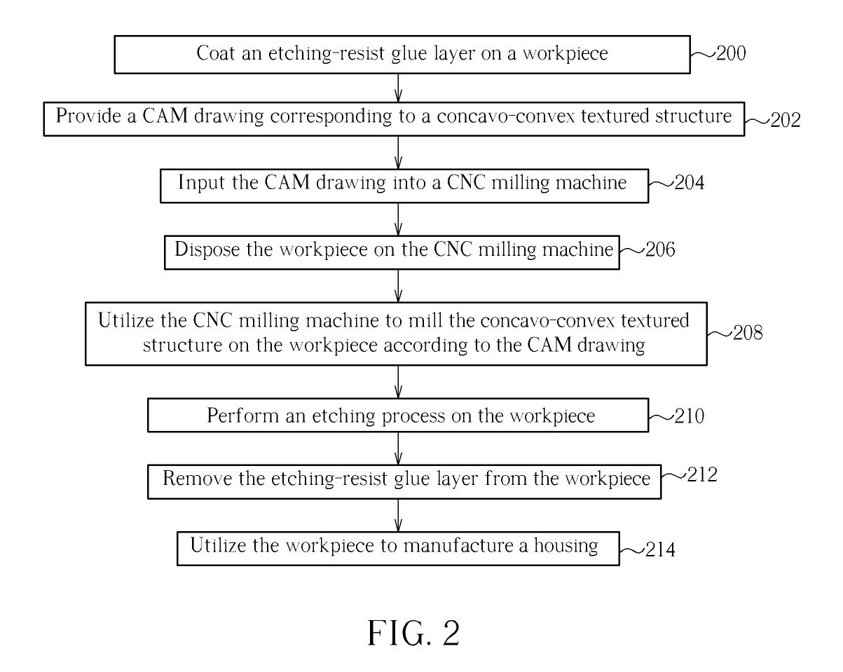

Please refer to FIG. 2, which is a flowchart of a method for forming the concavo-convex textured structure 18 on the main body 16 of the housing 14 in FIG. 1 according to the first preferred embodiment of the present invention. As shown in FIG. 2, the method includes the following steps.

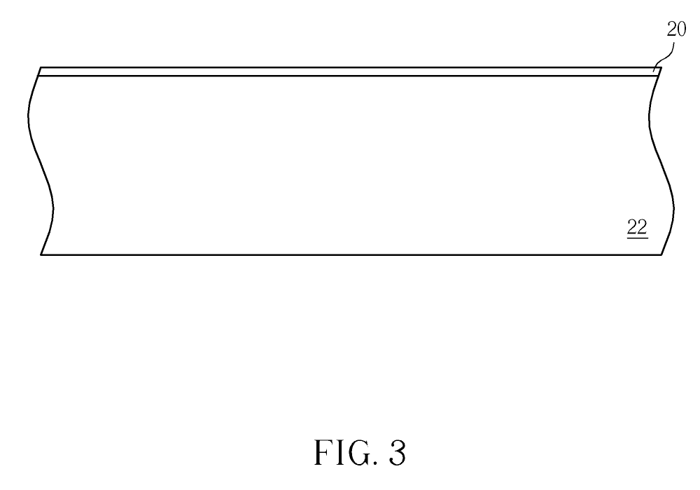

Step 200: Coat an etching-resist glue layer 20 on an unmilled workpiece 22 (as shown in FIG. 3);

Step 202: Provide a CAM drawing corresponding to the concavo-convex textured structure 18;

Step 204: Input the CAM drawing into a CNC milling machine;

Step 206: Dispose the workpiece 22 on the CNC milling machine;

Step 208: Utilize the CNC milling machine to mill the concavo-convex textured structure 18 on the workpiece 22 according to the CAM drawing;

Step 210: Perform an etching process on the milled workpiece 22 having the concavo-convex textured structure 18 thereon;

Step 212: Remove the etching-resist glue layer 20 from the workpiece 22;

Step 214: Utilize the workpiece 22 to manufacture the housing 14.

Further description for the method is provided as follows with reference to the attached drawings. As shown in FIG. 3, which is a partial cross-sectional diagram of the unmilled workpiece 22 with the etching-resist glue layer 20, the first step of the method is to coat the etching-resist glue layer 20 on the unmilled workpiece 22 (Step 200). Next, the subsequent steps are performed as mentioned in Steps 202-206, and the related description for Steps 202-206 is omitted herein for simplicity since Steps 202-206 are commonly seen in the prior art.

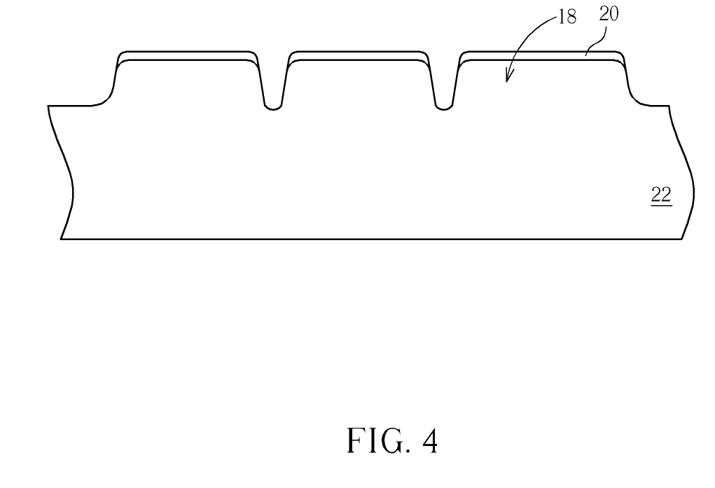

Next, please refer to FIG. 4, which is a partial cross-sectional diagram of the workpiece 22 in FIG. 3 having the concavo-convex textured structure 18 thereon. After the unmilled workpiece 22 with the etching-resist glue layer 20 is disposed on the CNC milling machine, the CNC milling machine starts to perform a milling process according to the CAM drawing and the concavo-convex textured structure 18 is formed on the workpiece 22 accordingly (Step 208). Thus, as shown in FIG. 4, the etching-resist glue layer 20 located above a concave portion of the concavo-convex textured structure 18 is removed by the milling process. Subsequently, as mentioned in Step 210, an etching process is performed on the milled workpiece 22 having the concavo-convex textured structure 18 thereon. That is, the milled workpiece 22 having the concavo-convex textured structure 18 thereon is disposed into a chemical solution so that a matt-surface texture may be formed on the concave portion of the concavo-convex textured structure 18. After the etching process is completed and the remnant etching-resist glue layer 20 is removed from the workpiece 22 (Step 212), the workpiece 22 may simultaneously have a shiny-surface texture on a convex portion of the concavo-convex textured structure 18 and a matt-surface texture on the concave portion of the concavo-convex textured structure 18. Finally, as mentioned in Step 214, the workpiece 22 may form the housing 14 as shown in FIG. 1 after performing some post processing (e.g. a sand blast treatment for trimming) on the workpiece 22, or the workpiece 22 may form the housing 14 as shown in FIG. 1 directly without performing any post processing.

It should be mentioned that Step 200 and Step 212 may be optional steps. That is, the workpiece 22 may be directly disposed into the chemical solution without coating the etching-resist glue layer 20 so that the workpiece 22 may only have an entire matt-surface texture thereon. Furthermore, the housing 14 may also be manufactured without performing the etching process in the present invention, meaning that Step 200, Step 210, and Step 212 are omitted for causing the concavo-convex textured structure 18 of the housing 14 to only have an entire shiny-surface texture thereon.

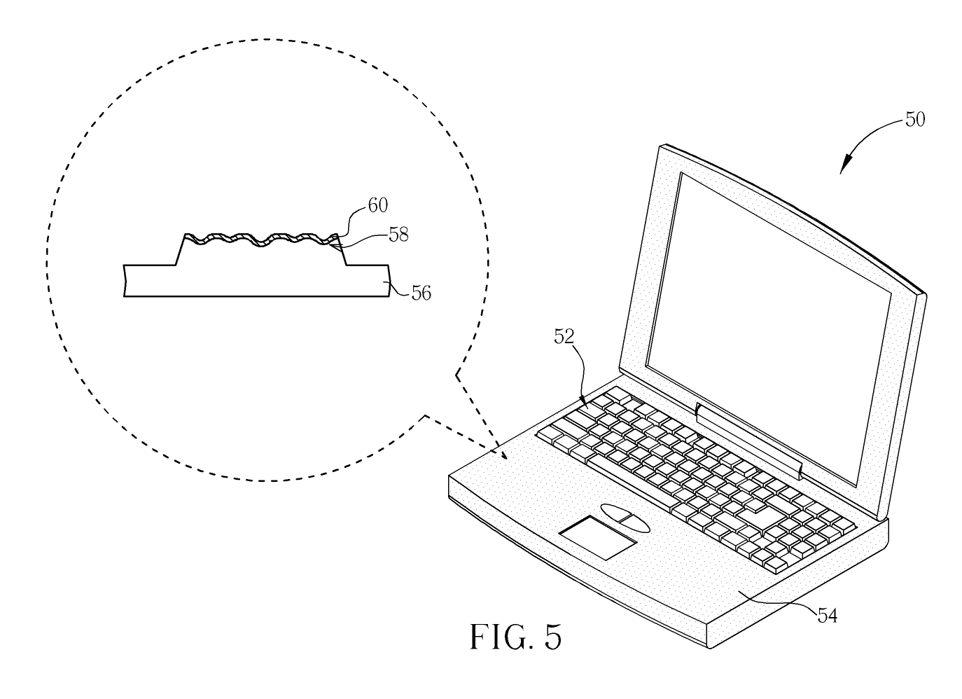

Besides milling the workpiece 22 to manufacture the housing 14 for the electronic device 10, the aforementioned CNC milling process may also be utilized to mill a concavo-convex textured structure on a mold for molding an ink layer of a film in an IMR (In Mold Roller) process. For example, please refer to FIG. 5, which is a diagram of an electronic device 50 according to a second preferred embodiment of the present invention. As shown in FIG. 5, the electronic device 50 is a notebook. The electronic device 50 includes a device body 52 and a housing 54. In the present invention, the device body 52 is regarded as the combination of other components (e.g. a keyboard, an LCD monitor, a motherboard, etc.) besides the housing 54 in the electronic device 50. The housing 54 is disposed on the device body 52 for protection of the device body 52. The housing 54 includes a main body 56, a concavo-convex textured structure 58, and an ink layer 60. As shown in FIG. 5, the concavo-convex textured structure 58 is formed on the main body 56, and the ink layer 60 is printed on the concavo-convex textured structure 58. More detailed description for forming the housing 54 is provided as follows.

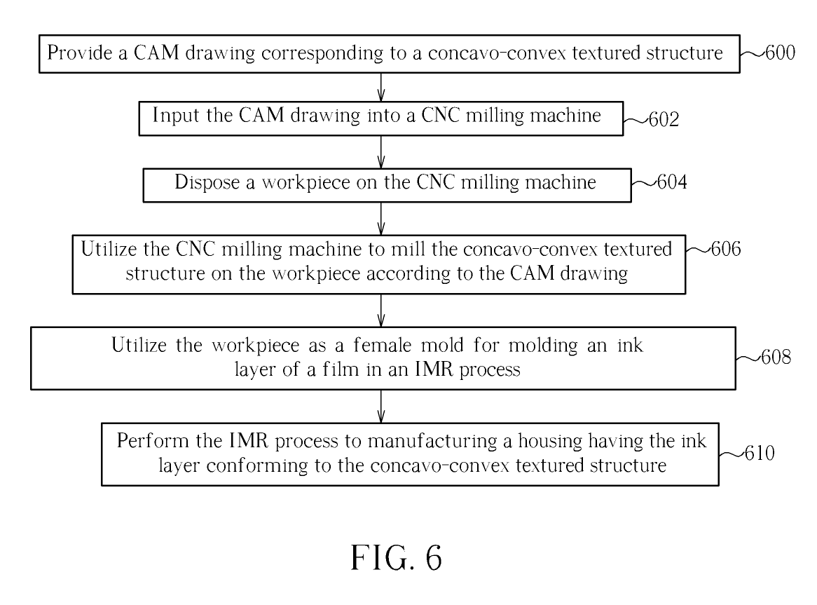

Please refer to FIG. 6, which is a flowchart of a method for forming the housing 54 in FIG. 5 according to the second preferred embodiment of the present invention. As shown in FIG. 6, the method includes the following steps.

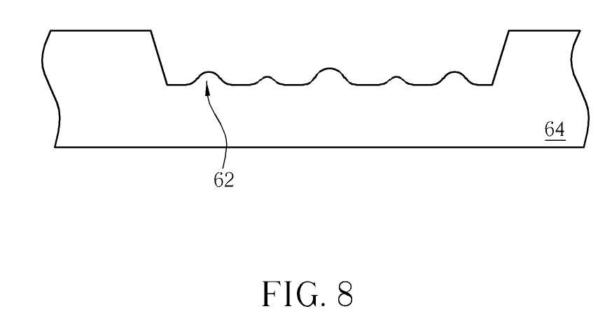

Step 600: Provide a CAM drawing corresponding to a concavo-convex textured structure 62 (as shown in FIG. 8);

Step 602: Input the CAM drawing into a CNC milling machine;

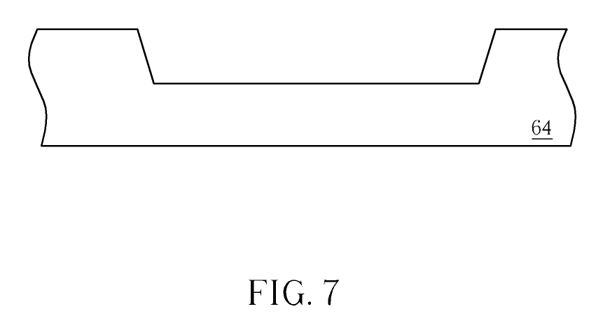

Step 604: Dispose a workpiece 64 (as shown in FIG. 7) on the CNC milling machine;

Step 606: Utilize the CNC milling machine to mill the concavo-convex textured structure 62 on the workpiece 64 according to the CAM drawing;

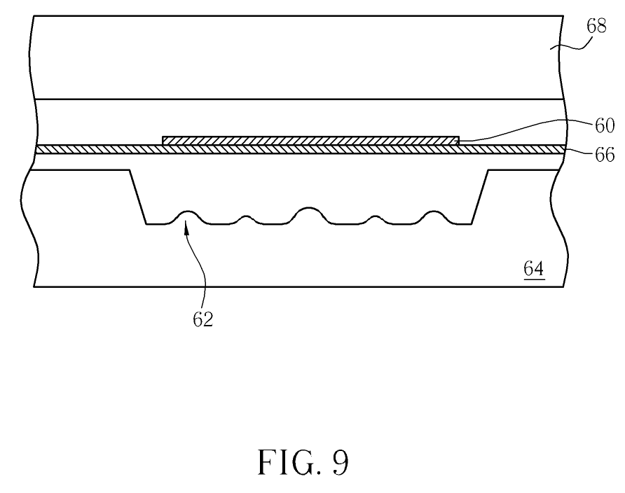

Step 608: Utilize the milled workpiece 64 having the concavo-convex textured structure 62 thereon as a female mold for molding the ink layer 60 of a film 66 (as shown in FIG. 9) in an IMR process;

Step 610: Perform the IMR process with the molded ink layer 60 of the film 66 so as to manufacture the housing 54 having the ink layer 60 conforming to the concavo-convex textured structure 62.

More detailed description for the method is provided as follows with reference to the attached drawings. As shown in FIG. 2 and FIG. 6, Steps 600-606 are similar to Steps 202-208, and the related description is therefore omitted herein. After Steps 600-606 are performed sequentially, the milled workpiece 64 having the concavo-convex textured structure 62 thereon is formed accordingly as shown in FIG. 8. Furthermore, as shown in FIG. 5 and FIG. 8, the shape of the concavo-convex textured structure 62 on the workpiece 64 is complementary to the shape of the concavo-convex textured structure 58 on the housing 54.

Next, please refer to FIG. 9, which is a partial cross-sectional diagram of the milled workpiece 64 being utilized as the female mold according to the second preferred embodiment of the present invention. As shown in FIG. 9, the milled workpiece 64 having the concavo-convex textured structure 62 thereon is utilized as the female mold (Step 608), and the film 66 with the ink layer 60 is then disposed between the milled workpiece 64 and a male mold 68. Next, the IMR process is performed with the molded ink layer 60 of the film 66 (Step 610). The IMR process is an ink-transfer technology, and the related molding steps are described briefly as follows with FIGS. 9, 10, and 11.

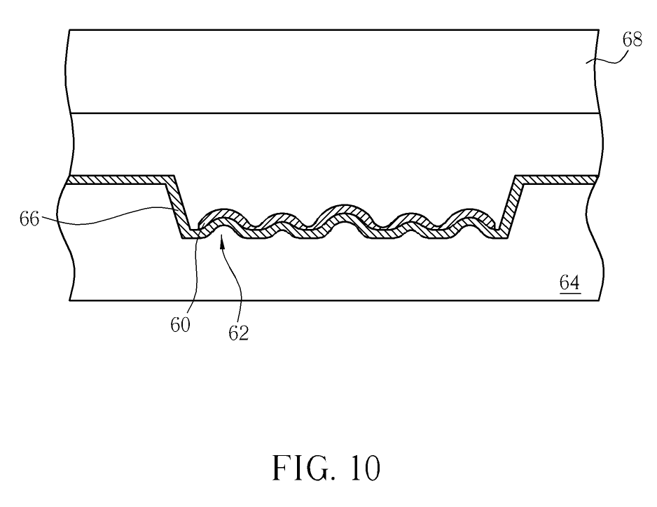

Please refer to FIG. 10, which is a partial cross-sectional diagram of the film 66 being attached to the milled workpiece 64 according to the second preferred embodiment of the present invention. That is, after the film 66 with the ink layer 60 is disposed between the milled workpiece 64 and the male mold 68, a vacuum pumping process is performed to make the film 66 attach to the milled workpiece 64 so that the shape of the ink layer 60 conforms to the concavo-convex textured structure 62 of the milled workpiece 64. In addition, since the concavo-convex textured structure 62 milled by the CNC milling machine has a smooth outline, the film 66 can be attached to the milled workpiece 64 closely and completely during the IMR process.

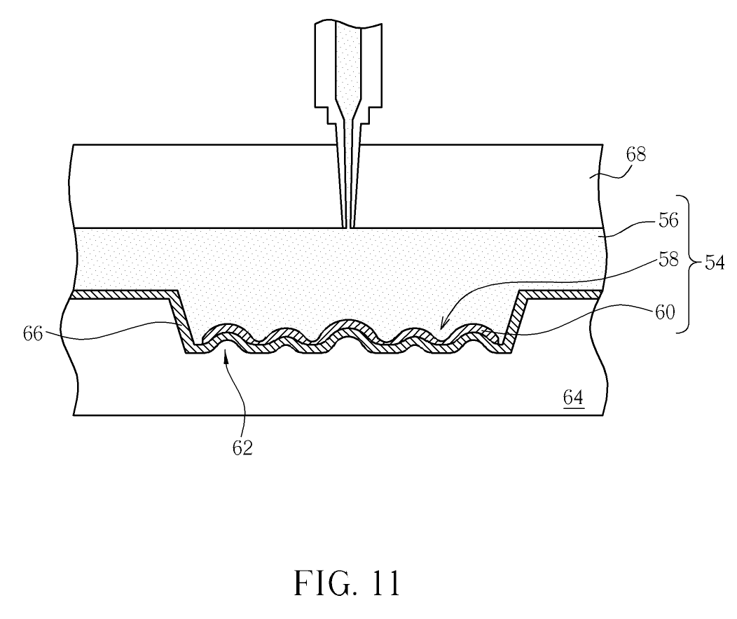

Next, please refer to FIG. 11, which is a partial cross-sectional diagram of the concavo-convex textured structure 58 and the main body 56 of the housing 54 being formed between the milled workpiece 64 and the male mold 68 in FIG. 10 according to the second preferred embodiment of the present invention. As shown in FIG. 11, an injection molding process is performed to form the concavo-convex textured structure 58 and the main body 56 of the housing 54 between the milled workpiece 64 and the male mold 68. Finally, after drawing out the housing 54 and removing the film 66 from the housing 54, the ink layer 60 conforming to the concavo-convex textured structure 62 is therefore printed on the concavo-convex textured structure 58 of the housing 54 so as to finish the IMR process. Furthermore, the post processing (e.g. a sand blast treatment for trimming) utilized in the first embodiment may also be performed on the concavo-convex textured structure 62 of the milled workpiece 64.

Compared with the prior art, in which a chemical etching process is utilized for forming a concavo-convex textured structure on a housing of an electronic device, the present invention utilizes a CNC milling process instead. Therefore, a complicated textured structure can be formed on a housing of an electronic device quickly by an automatic milling process so that related manufacturing cost and time may be reduced. Furthermore, the present invention may also perform an etching process on the milled housing for manufacturing a matt-surface texture on the housing. That is, the surface texture of the housing may have different variations with different steps performed in the present invention. On the other hand, in the present invention, the CNC milling process may also be utilized to mill a concavo-convex textured structure on a mold for molding an ink layer of a film in an IMR process. Since the concavo-convex textured structure milled by the CNC milling machine has a smooth outline, the film may be attached to the mold closely and completely, meaning that the mold having the concavo-convex textured structure thereon provided by the present invention may prevent the film from being broken during the IMR process.

Those skilled in the art will readily observe that numerous modifications and alterations of the device and method may be made while retaining the teachings of the invention.

What is claimed is:

1. A method for forming a concavo-convex textured structure on a housing of an electronic device, the method comprising:
providing a CAM (Computer-Aided Manufacturing) drawing corresponding to the concavo-convex textured structure;
inputting the CAM drawing into a CNC (Computer Numerical Control) milling machine;
disposing a workpiece on the CNC milling machine;
utilizing the CNC milling machine to mill the concavo-convex textured structure on the workpiece according to the CAM drawing; and
utilizing the workpiece to manufacture the housing of the electronic device.

2. The method of claim 1 further comprising:
coating an etching-resist glue layer on the unmilled workpiece;
performing an etching process on the milled workpiece having the concavo-convex textured structure thereon so as to form a matt-surface texture on a milled concave portion of the concavo-convex textured structure; and
removing the etching resist glue layer from the workpiece.

3. The method of claim 1 further comprising performing an etching process on the milled workpiece having the concavo-convex textured structure thereon so as to form a matt-surface texture thereon.

4. The method of claim 1, wherein utilizing the workpiece to manufacture the housing of the electronic device further comprises performing a sand blast treatment on the milled workpiece having the concavo-convex textured structure thereon for trimming.

5. The method of claim 1, wherein utilizing the workpiece to manufacture the housing of the electronic device comprises:
utilizing the milled workpiece having the concavo-convex textured structure thereon as a mold for molding an ink layer of a film in an IMR (In Mold Roller) process; and
performing the IMR process with the molded ink layer of the film on the housing of the electronic device so as to manufacture the housing having the ink layer conforming to the concavo-convex textured structure.

6. The method of claim 5, wherein utilizing the workpiece to manufacture the housing of the electronic device further comprises performing a sand blast treatment on the milled workpiece having the concavo-convex textured structure thereon for trimming.

7. A housing for an electronic device, the housing comprising:
a main body; and
a concavo-convex textured structure formed on the main body by utilizing a CNC milling machine according to a CAM drawing.

8. The housing of claim 7, wherein a matt-surface texture is formed on a milled concave portion of the concavo-convex textured structure by an etching process.

9. The housing of claim 7, wherein a matt-surface texture is formed on the concavo-convex textured structure by an etching process.

10. The housing of claim 7, wherein the concavo-convex textured structure is trimmed by a sand blast treatment.

11. The housing of claim 7 further comprising an ink layer printed on the concavo-convex textured structure by an IMR process, the concavo-convex textured structure being formed by a mold in the IMR process, the mold being milled by utilizing the CNC milling machine according to the CAM drawing.

12. An electronic device comprising:
a device body; and
a housing disposed on the device body, the housing comprising:
a main body; and
a concavo-convex textured structure formed on the main body by utilizing a CNC milling machine according to a CAM drawing.

13. The electronic device of claim 12, wherein a matt-surface texture is formed on a milled concave portion of the concavo-convex textured structure by an etching process.

14. The electronic device of claim 12, wherein a matt-surface texture is formed on the concavo-convex textured structure by an etching process.

15. The electronic device of claim 12, wherein the concavo-convex textured structure is trimmed by a sand blast treatment.

16. The electronic device of claim 12 further comprising an ink layer printed on the concavo-convex textured structure by an IMR process, the concavo-convex textured structure being formed by a mold in the IMR process, the mold being milled by utilizing the CNC milling machine according to the CAM drawing.
